(19) United States
(12) Patent Application Publication
(10) Pub. No.: US 2025/0079157 A1
(43) Pub. Date: Mar. 6, 2025

(54) METHODS OF IMPROVING METAL OXIDE DEPOSITION WITH NITROGEN OXIDE AND RELATED SYSTEMS

(71) Applicant: ENTEGRIS, INC., Billerica, MA (US)

(72) Inventors: Rong Zhao, Newtown, CT (US); Eric Condo, Shelton, CT (US); Bryan C. Hendrix, Danbury, CT (US); Lucas B. Henderson, Danbury, CT (US); Philip S.H. Chen, Bethel, CT (US)

(21) Appl. No.: 18/819,915

(22) Filed: Aug. 29, 2024

Related U.S. Application Data
(60) Provisional application No. 63/666,008, filed on Jun. 28, 2024.
(60) Provisional application No. 63/656,991, filed on Jun. 6, 2024.
(60) Provisional application No. 63/535,287, filed on Aug. 29, 2023.

(51) Int. Cl. H01L 21/02

(52) U.S. Cl. CPC H01L 21/02205; H01L 21/02178; H01L 21/02181; H01L 21/02183; H01L 21/02186; H01L 21/02189; H01L 21/02274; H01L 21/0228

(57) ABSTRACT

Methods improving metal oxide deposition with nitrogen oxide, related devices, and related systems are provided herein. The method comprises flowing an ozone gas from an ozone generator to a deposition chamber. The method comprises flowing a nitrogen oxide gas from a first source to the deposition chamber. The method comprises flowing a first precursor gas from a second source to the deposition chamber. The method comprises exposing a substrate located in the deposition chamber to at least one of the ozone gas, the nitrogen oxide gas, the first precursor gas, or any combination thereof. The method step of exposing is sufficient to form a film having a step coverage of at least 50%. The substrate has at least one structure with an aspect ratio of at least 10:1.

### CROSS-REFERENCE TO RELATED APPLICATIONS

This application claims the benefit under 35 USC 119 of U.S. Provisional Patent Application Nos. 63/535,287, filed Aug. 29, 2023, 63/656,991, fled Jun. 6, 2024, and 63/666,008 filed on Jun. 28, 2024, the disclosure of each is hereby incorporated herein by reference in its entirety.

### FIELD

The present disclosure relates to methods of improving metal oxide deposition with nitrogen oxides, related devices, and related systems.

### BACKGROUND

Films deposited via vapor deposition processes can result in non-uniform films. Problems associated with self-decomposition of the metal precursor source and insufficient diffusion, or dosage of the metal precursor source can result in non-uniform film deposition. In a similar manner, co-reactants can have associated problems with decomposition on the film surfaces, insufficient diffusion, insufficient dosage, or any combination thereof.

### SUMMARY

Some embodiments of the present disclosure relate to a method. In some embodiments, the method is a method of improving metal oxide deposition with a nitrogen oxide. In some embodiments, the method comprises flowing an ozone gas from an ozone generator to a deposition chamber. In some embodiments, the method comprises flowing a nitrogen oxide gas from a first source to the deposition chamber. In some embodiments, the method comprises flowing a first precursor gas from a second source to the deposition chamber. In some embodiments, the method comprises exposing a substrate located in the deposition chamber to at least one of the ozone gas and a nitrogen oxide gas, the first precursor gas, or any combination thereof. In some embodiments, the substrate has at least one structure with an aspect ratio of at least 10:1. In some embodiments, the exposing is sufficient to form a film having a step coverage of at least 50%.

Some embodiments relate to a device. In some embodiments, the device comprises a substrate having at least one structure with an aspect ratio of at least 10:1. In some embodiments, the device comprises a film located on at least one structure. In some embodiments, the film has a step coverage of at least 50%.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for forming a film, according to some embodiments.

FIG. 2 is a flowchart of a method for forming a film, according to some embodiments.

FIG. 3 is a block diagram of a system for a vapor deposition, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to methods of improving metal oxide deposition with nitrogen oxide and related systems and devices, among other things. Some film deposition processes have unpredictably poor step coverage at elevated temperatures. As disclosed herein, it has been discovered that introducing nitrous oxide (N₂O) into an vapor deposition process, unexpectedly results in improvements in step coverage at elevated temperatures (temperatures of at least 150° C.), when the nitrous oxide is supplied after an ozone generator and the resulting gas from an ozone generator (e.g., corona plasma) is used in combination with the nitrous oxide in a vapor deposition process. Accordingly, in some embodiments, methods for forming films (e.g., metal oxide films) on at least one high-aspect ratio structure of a substrate with a step coverage of at least 90% are provided.

Examples of vapor deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

As used herein, the term “step coverage” refers to a ratio of a thickness of a film on a first surface of a substrate to a thickness of the film on a second surface of the substrate. In some embodiments, the first surface of the substrate and the second surface of the substrate are different. For example, in some embodiments, the first surface of the substrate is a surface at the bottom of a high-aspect ratio structure (e.g., a trench) and the second surface of the substrate is a surface at the top of the high-aspect ratio structure (e.g., a trench). As disclosed herein, non-limiting examples of high-aspect ratio structures include, for example and without limitation, at least one of a trench, a plenum, a cavity, a hole, a channel, or any combination thereof. It will be appreciated that other structures would have high-aspect ratios and thus these shall not be limiting.

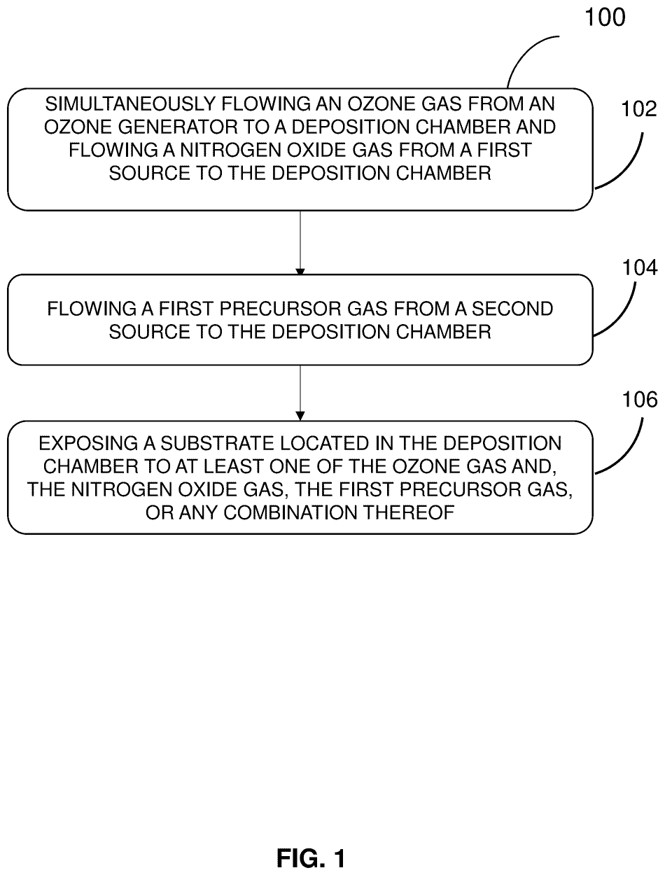

FIG. 1 is a flowchart of a method 100 of improving metal oxide deposition with nitrogen oxide, according to some embodiments. As shown in FIG. 1, the method 100 for forming a film may comprise one or more of the following steps: simultaneously flowing 102 an ozone gas from an ozone generator to a deposition chamber and flowing a nitrogen oxide gas from a first source to the deposition chamber; flowing 104 a first precursor gas from a second source to the deposition chamber; and exposing 106 a substrate located in the deposition chamber to a mixture of the ozone gas and the nitrogen oxide gas, with the first precursor gas supplied alternately, or together with the oxidizing mixture. In some embodiments, performing one or more of the steps 102, 104, and 106 comprises a deposition cycle. In some embodiments, the method 100 for forming a film comprises 1 deposition cycle to 100,000 deposition cycles, or any range or subrange between 1 deposition cycle and 100,000 deposition cycles.

In some embodiments, the method 100 of improving metal oxide deposition with nitrogen oxide comprises flowing 102 an ozone gas from an ozone generator to a deposition chamber. In some embodiments, the ozone gas comprises an ozone (O₃) component. In some embodiments, the ozone component comprises gas-component impurities from the impurities contained in the ozone gas generated by the ozone generator. In some embodiments, the ozone gas further comprises at least one of elemental oxygen (O), oxygen (O₂), water (H₂O), hydrogen peroxide (H₂O₂), nitric oxide (NO), dinitrogen pentoxide (N₂O₅), nitrogen dioxide (NO₂), NO₃, or any combination thereof.

In some embodiments, the simultaneously flowing 102 comprises introducing the ozone gas into a deposition chamber containing a substrate. In some embodiments, the simultaneously flowing 102 comprises supplying the ozone gas to a deposition chamber. In some embodiments, the simultaneously flowing 102 comprises pumping the ozone gas into a deposition chamber. In some embodiments, the simultaneously flowing 102 comprises pulsing the ozone gas into a deposition chamber.

In some embodiments, the method 100 of improving metal oxide deposition with nitrogen oxide comprises flowing a nitrogen oxide gas from a first source to the deposition chamber. The nitrogen oxide may be added downstream of the ozone generator. In some embodiments, the nitrogen oxide gas comprises at least one of nitrous oxide (N₂O), nitric oxide (NO), dinitrogen pentoxide (N₂O₅), nitrogen dioxide (NO₂), or any combination thereof. In some embodiments, the nitrogen oxide gas comprises nitrous oxide (N₂O). In some embodiments, the nitrogen oxide gas comprises nitric oxide (NO). In some embodiments, the nitrogen oxide gas comprises dinitrogen pentoxide (N₂O₅). In some embodiments, the nitrogen oxide gas comprises nitrous oxide (N₂O). In some embodiments, the nitrogen oxide gas is more reactive with Cl-metal bonds than O₃.

In some embodiments, the method 100 of improving metal oxide deposition with nitrogen oxide comprises flowing 104 comprises a first precursor gas from a second source to the deposition chamber. In some embodiments, the flowing 106 comprises supplying the first precursor gas to a deposition chamber. In some embodiments, the flowing 104 comprises pumping first precursor gas into a deposition chamber. In some embodiments, the flowing 104 comprises pulsing the first precursor gas into a deposition chamber

The first precursor gas comprises at least one of an elemental metal, a metal halide, a metal oxyhalide, an organometallic compound, a metalorganic complex, or any combination thereof. In some embodiments, the first precursor gas comprises at least one of comprises at least one of HfCl₄, ZrCl₄, AlCl₃, TiCl₄, TaC₁₅, NbCl₅, VCl₄, GaCl₃, InCl₃, or any combination thereof. In some embodiments, the first precursor gas comprises at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, boron, magnesium, gallium, indium, antimony, copper, phosphorous, arsenic, lithium, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis (dimethylamino) titanium (TDMAT), tertbutyliminotris (diethylamino) tantalum (TBTDET), pentakis (dimethylamino) tantalum (PDMAT), pentakis (ethylmethylamino) tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the first precursor gas comprises at least one of a rare earth betadiketonate compound (e.g., (La(THD)₃) and/or (Y(THD)₃)), a rare earth cyclopentadienyl (Cp) compound (e.g., La(iPrCp)₃); a rare earth amidinate compounds (e.g., lanthanum tris-formamidinate La(FAMD)₃); a cyclooctadienyl compounds including a rare earth metal; an alkylamido compounds (e.g., tris (dimethylamido) cyclopentadienyl hafnium (Hf(C₅H₅)(N(CH₃)₂)₃), tris (dimethylamido) cyclopentadienyl zirconium (Zr(C₅H₅)(N(CH₃)₂)₃), tetrakis-ethyl-methylamino hafnium (TEMAHf); tetrakis-ethyl-methylamino zirconium (TEMAZr); tetrakis (diethylamino) hafnium ((Et₂N)₄Hf or TDEAH); and/or tetrakis (dimethylamino) hafnium ((Me₂N)₄Hf or TDMAH)); an alkoxide; a halide compound of silicon; a silicon tetrachloride; a silicon tetrafluoride; a silicon tetraiodide; or any combination thereof.

In some embodiments, the first precursor gas comprises at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbony, or any combination thereof.

In some embodiments, the first precursor gas comprises at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCk, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof. In some embodiments, the vaporizable precursor comprises, consists of, or consists essentially of at least one of MoO₂Cl₂, MoOCl₄, WO₂Cl₂, WOCl₄, or any combination thereof.

In some embodiments, the first precursor gas comprises at least one of decaborane, (B₁₀H₁₄), pentaborane (B₅H₉), octadecaborane (B1₈H₂₂), boric acid (H₃BO₃), SbCl₃, SbCl₅, or any combination thereof. In some embodiments, the first precursor gas comprises at least one of at least one of AsCl₃, AsBr₃, AsF₃, AsF₅, AsH₃, As₄O₆, As₂Se₃, As₂S₂, As₂S₃, As₂S₅, As₂Te₃, B₄H₁₁, B₄H₁₀, B₃H₆N₃, BBr₃, BCl₃, BF₃, BF₃, O(C₂H₅)₂, BF₃.HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCl₃, SiCl₄, SiH₃Cl, NH₃, NH₃, Ar, Br₂, HBr, BrF₅, CO₂, CO, COCl₂, COF₂, Cl₂, ClF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCl₅, PF₃, PFS, SbH₃, SO₂, SF₆, SF₄, Si(OC₂H₅)₄, C₄H1₆Si₄O₄, Si(CH₃)₄, SiH(CH₃)₃, SiCl₄, Si₂Cl₆, TiCl₄, Xe, SiF₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof. It will be appreciated that other precursors may be used herein without departing from this disclosure.

In some embodiments, the method 100 of improving metal oxide deposition with nitrogen oxide comprises exposing 106 a substrate located in the deposition chamber to at least one of the ozone gas, the nitrogen oxide gas, the first precursor gas, or any combination thereof. In some embodiments, the method 100 of comprises exposing 106 a substrate located in the deposition chamber to the ozone gas. In some embodiments, the method 100 of comprises exposing 106 a substrate located in the deposition chamber to the nitrogen oxide gas. In some embodiments, the method 100 of comprises exposing 106 a substrate located in the deposition chamber to the first precursor gas.

In some embodiments, the exposing 106 is sufficient to bring at least one of the ozone gas and the nitrogen oxide gas, the first precursor gas, or any combination thereof and the substrate into immediate or close proximity, or direct physical contact. In some embodiments, the exposing 106 is sufficient to bring the first precursor gas and the substrate into immediate or close proximity, or direct physical contact. In some embodiments, the exposing 106 is sufficient to bring the ozone gas and the substrate into immediate or close proximity, or direct physical contact. In some embodiments, the exposing 106 is sufficient to bring the nitrogen oxide gas and the substrate into immediate or close proximity, or direct physical contact.

In some embodiment, the exposing 106 coats the substrate with the first precursor gas. In some embodiments, the exposing 106 coats the substrate with the ozone gas and nitrogen oxide gas.

In some embodiments, the substrate has at least one structure with an aspect ratio of at least 10:1. For example, in some embodiments, the substrate has at least one structure with an aspect ratio of at least 10:1, at least 20:1, at least 30:1, at least 40:1, at least 50:1, at least 60:1, at least 70:1, at least 80:1, or at least 90:1. In some embodiments, the substrate has at least one structure with an aspect ratio of 10:1 to 100:1, 10:1 to 90:1, 10:1 to 80:1, 10:1 to 70:1, 10:1 to 60:1, 10:1 to 50:1, 10:1 to 40:1, 10:1 to 30:1, 10:1 to 20:1, 20:1 to 100:1, 30:1 to 100:1, 40:1 to 100:1, 50:1 to 100:1, 60:1 to 100:1, 70:1 to 100:1, 80:1 to 100:1, or 90:1 to 100:1. In some embodiments, the at least one structure and the substrate are a single unitary piece. In some embodiments, the at least one structure and the substrate are separately manufactured and assembled together.

In some embodiments, the substrate is a high-aspect ratio substrate. For example, in some embodiments, a high-aspect ratio substrate comprises a substrate having at least one structure with a high-aspect ratio. In some embodiments, the substrate can have a plurality of structures, wherein each of the plurality of structures has a high-aspect ratio. The number of structures having a high-aspect ratio is not particularly limited and can range from one structure to thousands of structures. The at least one structure is not particularly limited and can include any structure having a high-aspect ratio as disclosed herein. In some embodiments, the at least one structure comprises at least one of a trench, a plenum, a cavity, a hole, a channel, or any combination thereof. Although high-aspect ratio structures are disclosed herein, it will be appreciated that embodiments disclosed herein also include substrates without high-aspect ratio structures.

The aspect ratio of the structure can refer to a ratio of two of a width, a depth, a height, a length, or a diameter, in any combination. In some embodiments, for example, the aspect ratio refers to the ratio of a depth of a circular hole (e.g., a pore, etc.) to a diameter of the circular hole (e.g., the pore, etc.). In some embodiments, the aspect ratio refers to the ratio of a depth of a non-circular hole (e.g., a trench, etc.) to a width of the non-circular hole (e.g., the trench, etc.). Non-limiting examples of substrates, including high-aspect ratio substrates, include, without limitation, at least one of a membrane, a showerhead, a liner, a tube, a gas line, a valve, an injector, a tray, or any combination thereof.

The substrate may comprise a substrate useful for microelectronic applications and/or semiconductor applications. In some embodiments, the substrate comprises at least one of a silicon, a silicon oxide, a silicon on insulator (SOI), a carbon doped silicon oxide, a silicon nitride, a doped silicon, a germanium, a gallium arsenide, a glass, a sapphire, a metal, a metal nitride, a metal alloy, or any combination thereof. In some embodiments, the substrate comprises a semiconductor. In some embodiments, the substrate comprises at least one of titanium, titanium nitride, tungsten, tungsten nitride, tantalum, tantalum nitride, or nay combination thereof.

In some embodiments, the exposing 106 the substrate located in the deposition chamber to at least one of the ozone gas and the nitrogen oxide gas, the first precursor gas, or any combination thereof is sufficient to form a film having a step coverage of at least 50%. For example, in some embodiments, the film has a step coverage of at least 50%, at least 55%, at least 60%, at least 65%, at least 70%, at least 75%, at least 80%, at least 85%, at least 90%, at least 95%, or greater. In some embodiments, the film has a step coverage of 50% to 100%, or any range or subrange between 50% and 100%. For example, in some embodiments, the film has a step coverage of 55% to 95%, 60% to 90%, 65% to 85%, or 70% to 80%. In some embodiments, the film has a step coverage of 50% to 95%, 50% to 90%, 50% to 85%, 50% to 80%, 50% to 75%, 50% to 70%, 50% to 65%, 50% to 60%, or 50% to 55%. In some embodiments, the film has a step coverage of 55% to 100%, 60% to 100%, 65% to 100%, 70% to 100%, 75% to 100%, 80% to 100%, 85% to 100%, 90% to 100%, or 95% to 100%.

In some embodiments, the film has a step coverage of at least 90%. For example, in some embodiments, the film has a step coverage of at least 90%, at least 91%, at least 92%, at least 93%, at least 94%, at least 95%, at least 96%, at least 97%, at least 98%, at least 99%, or greater. In some embodiments, the film has a step coverage of 90% to 100%, or any range or subrange between 90% and 100%. For example, in some embodiments, the film has a step coverage of 91% to 99%, 92% to 98%, 93% to 97%, or 94% to 96%. In some embodiments, the film has a step coverage of 90% to 99%, 90% to 98%, 90% to 97%, 90% to 96%, 90% to 95%, 90% to 94%, 90% to 93%, 90% to 92%, 90% to 91%. In some embodiments, the film has a step coverage of 91% to 100%, 92% to 100%, 93% to 100%, 94% to 100%, 95% to 100%, 96% to 100%, 97% to 100%, 98% to 100%, 99% to 100%.

In some embodiments, the film comprises a metal oxide. In some embodiments, the film comprises at least one of a hafnium oxide, a zirconium oxide, an aluminum oxide, a titanium oxide, a tantalum oxide, a niobium oxide, a vanadium. In some embodiments, for example, the film comprises a hafnium oxide. In some embodiments, the film comprises a zirconium oxide. In some embodiments, the film comprises an aluminum oxide. In some embodiments, the film comprises a titanium oxide. In some embodiments, the film comprises a tantalum oxide. In some embodiments, the film comprises a niobium oxide. In some embodiments, the film comprises a vanadium oxide. In some embodiments, the film comprises a gallium oxide. In some embodiments, the film comprises an indium oxide.

The film may have a concentration of less than 1×10²⁰ hydrogen atoms per cubic centimeter as measured by Secondary lon Mass Spectrometry (SIMS). For example, in some embodiments, the film may have a concentration of less than 1×10²⁰ hydrogen atoms per cubic centimeter, less than 0.9×10²⁰ hydrogen atoms per cubic centimeter, less than 0.8×10²⁰ hydrogen atoms per cubic centimeter, less than 0.7×10²⁰ hydrogen atoms per cubic centimeter, less than 0.6×10²⁰ hydrogen atoms per cubic centimeter, less than 0.5×10²⁰ hydrogen atoms per cubic centimeter, less than 0.4×10²⁰ hydrogen atoms per cubic centimeter, less than 0.3×10²⁰ hydrogen atoms per cubic centimeter, less than 0.2×10²⁰ hydrogen atoms per cubic centimeter, or less than 0.1×10²⁰ hydrogen atoms per cubic centimeter.

In some embodiments, the nitrogen oxide in the second precursor gas, prevents premature decomposition of O₃. In some embodiments, the nitrogen oxide in the second precursor gas, may occupy active site of a plurality of O₃ decomposition catalyst on the deposition chamber. In some embodiments, the nitrogen oxide in the second precursor gas, has a longer life compared to O₃ in a coated deposition chamber and in deep structures of the substrate that is coated with metal oxides in forming the film.

In some embodiments, the exposing 106 is a duration of 0.01 seconds to 60 minutes, or longer, or any range or subrange between 0.01 s second and 60 minutes. For example, in some embodiments, the duration is a duration of 0.01 seconds to 50 minutes, 0.01 seconds to 40 minutes, 0.01 seconds to 30 minutes, 0.01 seconds to 20 minutes, 0.01 seconds to 10 minutes, 0.01 seconds to 1 minute, 0.01 seconds to 45 seconds, 0.01 seconds to 30 seconds, 0.01 seconds to 15 seconds, 0.01 seconds to 10 seconds, 0.01 seconds to 5 seconds, 0.01 seconds to 3 seconds, 0.01 seconds to 1 seconds, 0.01 seconds to 0.5 seconds, 0.01 seconds to 0.1 seconds, or 0.01 seconds to 0.05 seconds. In some embodiments, the duration is a duration of 0.05 seconds to 60 minutes, 0.10 seconds to 60 minutes, 0.2 seconds to 60 minutes, 0.3 seconds to 60 minutes, 0.4 seconds to 60 minutes, 0.5 seconds to 60 minutes, 0.6 seconds to 60 minutes, 0.7 seconds to 60 minutes, 0.8 seconds to 60 minutes, 0.9 seconds to 60 minutes, 1 seconds to 60 minutes, 3 seconds to 60 minutes, 5 seconds to 60 minutes, 15 seconds to 60 minutes, 30 seconds to 60 minutes, 1 minute to 60 minutes, 10 minutes to 60 minutes, 20 minutes to 60 minutes, 30 minutes to 60 minutes, 40 minutes to 60 minutes, or 50 minutes to 60 minutes.

In some embodiments, the exposing 106 is a duration of 0.01 seconds to 5 minutes, or longer, or any range or subrange between 0.01 seconds and 5 minutes. For example, in some embodiments, the duration is a duration of 0.01 seconds to 4 minutes, 0.01 seconds to 3 minutes, 0.01 seconds to 2 minutes, 0.01 seconds to 2 minutes, 0.01 seconds to 1 minute, 0.01 seconds to 50 seconds, 0.01 seconds to 40 seconds, 0.01 seconds to 30 seconds, 0.01 seconds to 20 seconds, 0.01 seconds to 10 seconds, 0.01 seconds to 5 seconds, or 0.01 seconds to 3 seconds, 0.01 seconds to 1 seconds, 0.01 seconds to 0.5 seconds, 0.01 seconds to 0.1 seconds, or 0.01 seconds to 0.05 seconds. In some embodiments, the duration is a duration of 0.05 seconds to 5 minutes, 0.05 seconds to 5 minutes, 0.10 seconds to 5 minutes, 0.2 seconds to 5 minutes, 0.3 seconds to 5 minutes, 0.4 seconds to 5 minutes, 0.5 seconds to 5 minutes, 0.6 seconds to 5 minutes, 0.7 seconds to 5 minutes, 0.8 seconds to 5 minutes, 0.9 seconds to 5 minutes, 1 seconds to 5 minutes, 3 seconds to 5 minutes, 5 seconds to 5 minutes, 15 seconds to 5 minutes, 30 seconds to 5 minutes, 1 minute to 5 minutes, 2 minutes to 5 minutes, 3 minutes to 5 minutes, or 4 minutes to 5 minutes.

In some embodiments, the deposition chamber has a temperature in a range of 100° C. to 500° C., or any range or subrange between 100° C. and 500° C. For example, in some embodiments, the deposition chamber has a temperature in a range of 100° C. to 475° C., 100° C. to 450° C., 100° C. to 425° C., 100° C. to 400° C., 100° C. to 375° C., 100° C. to 350° C., 100° C. to 325° C., 100° C. to 300° C., 100° C. to 275° C., 100° C. to 250° C., 100° C. to 225° C., 100° C. to 200° C., 100° C. to 175° C., 100° C. to 150° C., 100° C. to 125° C., 125° C. to 500° C., 150° C. to 500° C., 175° C. to 500° C., 200° C. to 500° C., 225° C. to 500° C., 250° C. to 500° C., 275° C. to 500° C., 300° C. to 500° C., 325° C. to 500° C., 350° C. to 500° C., 375° C. to 500° C., 400° C. to 500° C., 425° C. to 500° C., 450° C. to 500° C., or 475° C. to 500° C.

In some embodiments, the exposing comprises simultaneously exposing the substrate to the ozone gas and the nitrogen oxide gas. In some embodiments, the nitrogen oxide gas is added downstream of the ozone generator to simultaneously expose the substrate to the ozone gas and the nitrogen oxide gas.

In some embodiments, the step of exposing comprises simultaneously exposing the substrate to the ozone gas and the nitrogen oxide gas. In some embodiments, the step of exposing comprises separately exposing the substrate to the first precursor gas.

In some embodiments, exposing is sufficient to form a film on the at least one structure having a step coverage of 50% to 99%, or any range or subrange between 50% and 99%. In some embodiments, for example, exposing is sufficient to form a film on the at least one structure having a step coverage of 55% to 95%, 60% to 90%, 65% to 85%, or 70% to 80%. In some embodiments, exposing is sufficient to form a film on the at least one structure having a step coverage of 55% to 99%, 60% to 99%, 65% to 99%, 70% to 99%, 75% to 99%, 80% to 99%, 85% to 99%, 90% to 99%, or 95% to 99%. In some embodiments, exposing is sufficient to form a film on the at least one structure having a step coverage of 50% to 95%, 50% to 90%, 50% to 85%, 50% to 80%, of 50% to 75%, 50% to 70%, 50% to 65%, 50% to 60%, or 50% to 55%.

In some embodiments, the exposing the substrate to the ozone gas and the nitrogen oxide gas comprises a second precursor gas. In some embodiments, the second precursor gas comprises 10% to 60% by volume of the nitrogen oxide gas based on a total volume of the second precursor gas, or any range or subrange between 10% and 60%. For example, in some embodiments, the volume of the nitrogen oxide gas based on a total volume of the second precursor gas may be 15% to 55%, 20% to 50%, 25% to 45%, or 30% to 40%. In some embodiments, the volume of the nitrogen oxide gas based on a total volume of the second precursor gas may be 10% to 55%, 10% to 50%, 10% to 45%, 10% to 40%, 10% to 35%, 10% to 30%, 10% to 25%, 10% to 20%, or 10% to 15%. In some embodiments, the volume of the nitrogen oxide gas based on a total volume of the second precursor gas may be 15% to 60%, 20% to 60%, 25% to 60%, 30% to 60%, 35% to 60%, 40% to 60%, 45% to 60%, 50% to 60%, or 55% to 60%.

In some embodiments, the second precursor gas comprises 40% to 90% by volume of the second precursor gas based on the total volume of the second precursor gas, or any range or subrange between 40% and 90%. For example, in some embodiments, the volume of the second precursor gas based on a total volume of the second precursor gas may be 45% to 85%, 50% to 80%, 55% to 75%, or 60% to 70%. In some embodiments, the volume of the second precursor gas based on a total volume of the second precursor gas may be 40% to 85%, 40% to 80%, 40% to 75%, 40% to 70%, 40% to 65%, 40% to 60%, 40% to 55%, 40% to 50%, or 40% to 45%. In some embodiments, the volume of the second precursor gas based on a total volume of the second precursor gas may be 45% to 90%, 50% to 90%, 55% to 90%, 60% to 90%, 65% to 90%, 70% to 90%, 75% to 90%, 80% to 90%, or 85% to 90%.

In some embodiments, the exposing the substrate to the ozone gas and the nitrogen oxide gas comprises a second precursor gas. In some embodiments, the second precursor gas comprises 40% to 60% by volume of the nitrogen oxide gas based on a total volume of the second precursor gas, or any range or subrange between 40% and 60%. For example, in some embodiments, the volume of the nitrogen oxide gas based on a total volume of the second precursor gas may be 35% to 55%, or 40% to 50%. In some embodiments, the volume of the nitrogen oxide gas based on a total volume of the second precursor gas may be 40% to 55%, 40% to 50%, or 40% to 45%. In some embodiments, the volume of the nitrogen oxide gas based on a total volume of the second precursor gas may be 45% to 60%, 50% to 60%, or 55% to 60%.

In some embodiments, the second precursor gas comprises 40% to 60% by volume of the second precursor gas based on the total volume of the second precursor gas, or any range or subrange between 40% and 60%. For example, in some embodiments, the volume of the second precursor gas based on a total volume of the second precursor gas may be 35% to 55%, or 40% to 50%. In some embodiments, the volume of the second precursor gas based on a total volume of the second precursor gas may be 40% to 55%, 40% to 50%, or 40% to 45%. In some embodiments, the volume of the second precursor gas based on a total volume of the second precursor gas may be 45% to 60%, 50% to 60%, or 55% to 60%.

In some embodiments, the deposition chamber has a temperature of 150° C. to 350° C. In some embodiments, the deposition chamber has a temperature of 150° C. to 300° C., 150° C. to 250° C., or 150° C. to 200° C. In some embodiments, the deposition chamber has a temperature of 200° C. to 350° C., 250° C. to 350° C., or 300° C. to 350° C.

In some embodiments, the presence of the nitrogen oxide gas may extend the lifetime of the O₃ component in the deposition chamber. In some embodiments, the nitrogen oxide may be useful in sustaining the O₃ component as the O₃ component travels to a depth with a high-aspect ratio structure. In some embodiments, the nitrogen oxide may prevent premature decomposition of the O₃ component to sustain the O₃ component delivery to the substrate. In some embodiments, the nitrogen oxide has a longer life cycle compared to O₃ component in a deposition chamber. In some embodiments, the deposition chamber may be coated.

In some embodiments, the method does not comprise flowing the nitrogen oxide gas from the first source to the ozone generator. In some embodiments, when nitrogen oxide gas is not flowed to the ozone generator, the method step of exposing, is sufficient to increase a growth rate cycle of the substrate.

Some embodiments relate to a device. In some embodiments, the device comprises a substrate having at least one structure with an aspect ratio of at least 10:1 as described herein. In some embodiments, the device comprises a film located on the at least one structure, as described herein. In some embodiments, the film has a step coverage of at least 50%. For example, in some embodiments, the film has a step coverage of at least 50%, at least 55%, at least 60%, at least 65%, at least 70%, at least 75%, at least 80%, at least 85%, at least 90%, at least 95%, or greater. In some embodiments, the film has a step coverage of 50% to 100%, or any range or subrange between 50% and 100%. For example, in some embodiments, the film has a step coverage of 55% to 95%, 60% to 90%, 65% to 85%, or 70% to 80%. In some embodiments, the film has a step coverage of 50% to 95%, 50% to 90%, 50% to 85%, 50% to 80%, 50% to 75%, 50% to 70%, 50% to 65%, 50% to 60%, or 50% to 55%. In some embodiments, the film has a step coverage of 55% to 100%, 60% to 100%, 65% to 100%, 70% to 100%, 75% to 100%, 80% to 100%, 85% to 100%, 90% to 100%, or 95% to 100%.

In some embodiments, the film has a step coverage of at least 90%. For example, in some embodiments, the film has a step coverage of at least 90%, at least 91%, at least 92%, at least 93%, at least 94%, at least 95%, at least 96%, at least 97%, at least 98%, at least 99%, or greater. In some embodiments, the film has a step coverage of 90% to 100%, or any range or subrange between 90% and 100%. For example, in some embodiments, the film has a step coverage of 91% to 99%, 92% to 98%, 93% to 97%, or 94% to 96%. In some embodiments, the film has a step coverage of 90% to 99%, 90% to 98%, 90% to 97%, 90% to 96%, 90% to 95%, 90% to 94%, 90% to 93%, 90% to 92%, 90% to 91%. In some embodiments, the film has a step coverage of 91% to 100%, 92% to 100%, 93% to 100%, 94% to 100%, 95% to 100%, 96% to 100%, 97% to 100%, 98% to 100%, 99% to 100%.

In some embodiments, the film comprises a metal oxide. In some embodiments, the film comprises at least one of a hafnium oxide, a zirconium oxide, an aluminum oxide, a titanium oxide, a tantalum oxide, a niobium oxide, or a vanadium oxide. In some embodiments, for example, the film comprises a hafnium oxide. In some embodiments, the film comprises a zirconium oxide. In some embodiments, the film comprises an aluminum oxide. In some embodiments, the film comprises a titanium oxide. In some embodiments, the film comprises a tantalum oxide. In some embodiments, the film comprises a niobium oxide. In some embodiments, the film comprises a vanadium oxide. In some embodiments, the film comprises a gallium oxide. In some embodiments, the film comprises an indium oxide. In some embodiments, the film comprises a metalloid oxide, e.g., a silicon oxide.

The film may have a thickness of 1 nm to 5 μm, or any range or subrange between 1 nm and 5 μm. In some embodiments, for example, the film has a thickness of 1 nm to 4 μm, 1 nm to 3 μm, 1 nm to 2 μm, 1 nm to 1 μm, 1 nm to 900 nm, 1 nm to 800 nm, 1 nm to 700 nm, 1 nm to 600 nm, 1 nm to 500 nm, 1 nm to 400 nm, 1 nm to 300 nm, 1 nm to 200 nm, or 1 nm to 100 nm. In some embodiments, for example, the film has a thickness of 100 nm to 5 μm, 200 nm to 5 μm, 300 nm to 5 μm, 400 nm to 5 μm, 500 nm to 5 μm, 600 nm to 5 μm, 700 nm to 5 μm, 800 nm to 5 μm, 900 nm to 5 μm, 1 μm to 5 μm, 2 μm to 5 μm, 3 μm to 5 μm, or 4 μm to 5 μm.

In some embodiments, the film may have a concentration of less than 1×10²⁰ hydrogen atoms per cubic centimeter as measured by Secondary lon Mass Spectrometry (SIMS). For example, in some embodiments, the film may have a concentration of less than 1×10²⁰ hydrogen atoms per cubic centimeter, less than 0.9×10²⁰ hydrogen atoms per cubic centimeter, less than 0.8×10²⁰ hydrogen atoms per cubic centimeter, less than 0.7×10²⁰ hydrogen atoms per cubic centimeter, less than 0.6×10²⁰ hydrogen atoms per cubic centimeter, less than 0.5×10²⁰ hydrogen atoms per cubic centimeter, less than 0.4×10²⁰ hydrogen atoms per cubic centimeter, less than 0.3×10²⁰ hydrogen atoms per cubic centimeter, less than 0.2×10²⁰ hydrogen atoms per cubic centimeter, or less than 0.1×10²⁰ hydrogen atoms per cubic centimeter.

In some embodiments, the film may have a concentration of less than 9×10¹⁹ hydrogen atoms per cubic centimeter, less than 8×10¹⁹ hydrogen atoms per cubic centimeter, less than 7×10¹⁹ hydrogen atoms per cubic centimeter, less than 7×10¹⁹ hydrogen atoms per cubic centimeter, less than 6×10¹⁹ hydrogen atoms per cubic centimeter, less than 5×10¹⁹ hydrogen atoms per cubic centimeter, less than 4×10¹⁹ hydrogen atoms per cubic centimeter, less than 3×10¹⁹ hydrogen atoms per cubic centimeter, less than 2×10¹⁹ hydrogen atoms per cubic centimeter, less than 1×10¹⁹ hydrogen atoms per cubic centimeter as measured by SIMS.

In some embodiments, the film may have a concentration of less than less than 10×10¹⁸ carbon atoms per cubic centimeter as measured by SIMS. For example, in some embodiments, the film has a concentration of less than 10×10¹⁸ carbon atoms per cubic centimeter, less than 9×10¹⁸ carbon atoms per cubic centimeter, less than 8×10¹⁸ carbon atoms per cubic centimeter, less than 7×10¹⁸ carbon atoms per cubic centimeter, less than 6×10¹⁸ carbon atoms per cubic centimeter, less than 5×10¹⁸ carbon atoms per cubic centimeter, less than 4×10¹⁸ carbon atoms per cubic centimeter, less than 3×10¹⁸ carbon atoms per cubic centimeter, less than 2×10¹⁸ carbon atoms per cubic centimeter, less than 1×10¹⁸ carbon atoms per cubic centimeter.

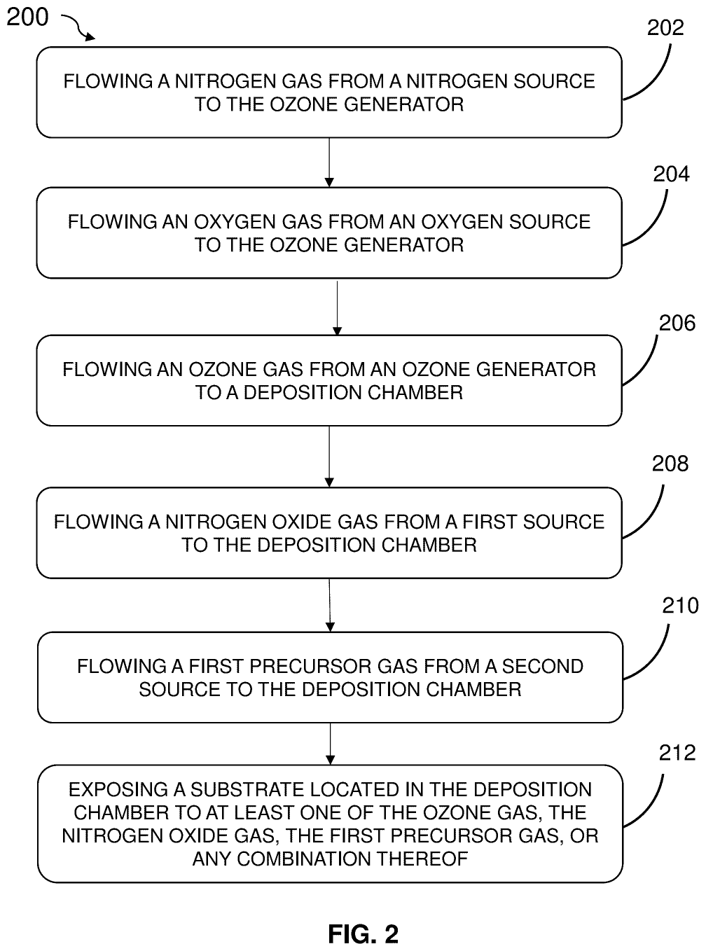

FIG. 2 is a flowchart of a method 200 of improving metal oxide deposition with nitrogen oxide, according to some embodiments. As shown in FIG. 2, the method 100 for forming a film may comprise one or more of the following steps: flowing 202 a nitrogen gas from a nitrogen source to the ozone generator; flowing 204 an oxygen gas from an oxygen source to the ozone generator; flowing 206 an ozone gas from an ozone generator to a deposition chamber; flowing 208 a nitrogen oxide gas from a first source to the deposition chamber; flowing 210 a first precursor gas from a second source to the deposition chamber; and exposing 212 a substrate located in the deposition chamber to at least one of the ozone gas, the nitrogen oxide gas, the first precursor gas, or any combination thereof. In some embodiments, performing one or more of the steps 202, 204, 206, 208, 210, and 212 comprises a deposition cycle. In some embodiments, the method 200 for forming a film comprises 1 deposition cycle to 100,000 deposition cycles, or any range or subrange between 1 deposition cycle and 100,000 deposition cycles. Method 200 generally functions in the same manner as method 100 except that method 200 further comprises flowing 202 a nitrogen gas and flowing 204 an oxygen gas to the ozone generator. In some embodiments, the ozone generator produces the ozone gas.

In some embodiments, the nitrogen gas comprises N₂. In some embodiments, the nitrogen gas comprises 50 parts per million (ppm) to 200 ppm of N₂, or any range or subrange between 50 ppm and 200 ppm. For example, in some embodiments, the nitrogen gas comprises N₂ in the range of 60 ppm to 190 ppm, 70 ppm to 180 ppm, 80 ppm to 170 ppm, 90 ppm to 160 ppm, 100 ppm to 150 ppm, 110 ppm to 140 ppm, or 120 ppm to 140 ppm. In some embodiments, the nitrogen gas comprises N₂ in the range of 50 ppm to 180 ppm, 50 ppm to 160 ppm, 50 ppm to 140 ppm, 50 ppm to 120 ppm, 50 ppm to 100 ppm, 50 ppm to 80 ppm, or 50 ppm to 60 ppm. In some embodiments, the nitrogen gas comprises N₂ in the range of 60 ppm to 200 ppm, 800 ppm to 200 ppm, 100 ppm to 200 ppm, 120 ppm to 200 ppm, 140 ppm to 200 ppm, 160 ppm to 200 ppm, or 180 ppm to 200 ppm.

In some embodiments, the nitrogen gas and the oxygen gas converge to produce a feed gas. In some embodiments, the feed gas is supplied to the ozone generator to produce the ozone gas.

In some embodiments, the nitrogen gas comprises 10% to 30% by volume of N₂ based on a total volume of the feed gas, or any range or subrange between 10% and 30%. For example, in some embodiments, the volume of N₂ based on a total volume of the feed gas may be 12% to 28%, 14% to 26%, 16% to 24%, or 18% to 22%. In some embodiments, the volume of N₂ based on a total volume of the feed gas may be 10% to 28%, 10% to 26%, 10% to 24%, 10% to 22%, 10% to 20%, 10% to 18%, 10% to 16%, 10% to 14%, or 10% to 12%. In some embodiments, the volume of N₂ based on a total volume of the feed gas may be 12% to 30%, 14% to 30%, 16% to 30%, 18% to 30%, 20% to 30%, 22% to 30%, 24% to 30%, 26% to 30%, or 28% to 30%.

In some embodiments, the feed gas comprises 70% to 98% by volume of O₂ based on a total volume of the feed gas, or any range or subrange between 70% and 98%. For example, in some embodiments, the volume of O₂ based on a total volume of the feed gas may be 72% to 88%, 74% to 86%, 76% to 84%, or 78% to 82%. In some embodiments, the volume of O₂ based on a total volume of the feed gas may be 70% to 88%, 70% to 86%, 70% to 84%, 70% to 82%, 70% to 80%, 70% to 88%, 70% to 86%, 70% to 84%, or 70% to 82%. In some embodiments, the volume of O₂ based on a total volume of the feed gas may be 72% to 80%, 74% to 90%, 76% to 90%, 78% to 90%, 70% to 90%, 72% to 90%, 74% to 90%, 76% to 90%, or 78% to 90%.

In some embodiments, the feed gas comprises at least 1% by volume of N₂ based on a total volume of the feed gas. In some embodiments, the feed gas comprises at least 10% by volume of N₂ based on a total volume of the feed gas. In some embodiments, the feed gas comprises at least 15% by volume of N₂ based on a total volume of the feed gas. In some embodiments, the feed gas comprises at least 20% by volume of N₂ based on a total volume of the feed gas. In some embodiments, the feed gas comprises at least 25% by volume of N₂ based on a total volume of the feed gas. In some embodiments, the feed gas comprises at least 30% by volume of N₂ based on a total volume of the feed gas. In some embodiments, the feed gas comprises at least 35% by volume of N₂ based on a total volume of the first feed gas. In some embodiments, the feed gas comprises 2% to 40% by volume of N₂ based on the total volume of the feed gas, or any range or subrange between 2% and 40%. For example, in some embodiments, the feed gas comprises 2% to 40%, 2% to 35%, 2% to 30%, 2% to 25%, 2% to 20%, 2% to 15%, 2% to 10%, 2% to 5%, 10% to 40%, 15% to 40%, 20% to 40%, 25% to 40%, 30% to 40%, or 35% to 40% by weight of N₂ based on the total volume of the feed gas.

In some embodiments, the feed gas comprises at least 50% by volume of O₂ based on the total volume of the feed gas. In some embodiments, the feed gas comprises at least 60% by volume of O₂ based on the total volume of the feed gas. In some embodiments, the feed gas comprises at least 65% by volume of O₂ based on the total volume of the feed gas. In some embodiments, the feed gas comprises at least 70% by volume of O₂ based on the total volume of the feed gas. In some embodiments, the feed gas comprises at least 75% by volume of O₂ based on the total volume of the feed gas. In some embodiments, the feed gas comprises at least 80% by volume of O₂ based on the total volume of the feed gas. In some embodiments, the feed gas comprises at least 85% by volume of O₂ based on the total volume of the feed gas. In some embodiments, the feed gas comprises at least 90% by volume of O₂ based on the total volume of the feed gas. In some embodiments, the feed gas comprises 50% to 95% by volume of O₂ based on the total volume of the feed gas, or any range or subrange between 50% and 95%. For example, in some embodiments, the feed gas comprises 50% to 95%, 50% to 90%, 50% to 85%, 50% to 80%, 50% to 75%, 50% to 70%, 50% to 65%, 50% to 60%, 50% to 55%, 55% to 95%, 60% to 95%, 65% to 95%, 70% to 95%, 75% to 95%, 80% to 95%, 85% to 95%, or 90% to 95% by volume of O₂ based on the total volume of the feed gas. In an embodiment, the feed gas is just O₂ and N₂.

In some embodiments, the feed gas comprises 0.1% to 20% by volume of H₂ based on the total volume of the feed gas, or any range or subrange between 0.1% and 20%. For example, in some embodiments, the volume of H₂ based on the total volume of the feed gas may be 0.5% to 18%, 1% to 16%, 3% to 14%, 5% to 12%, or 7% to 10%. In some embodiments, the volume of H₂ based on the total volume of the feed gas may be 0.1% to 19%, 0.1% to 18%, 0.1% to 17%, 0.1% to 16%, 0.1% to 15%, 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, 0.1% to 1%, 0.1% to 0.9%, 0.1% to 0.8%, 0.1% to 0.7%, 0.1% to 0.6%, 0.1% to 0.5%, 0.1% to 0.4%, 0.1% to 0.3%, or 0.1% to 0.2%. In some embodiments, the volume of H₂ based on the total volume of the feed gas may be 0.5% to 20%, 1% to 20%, 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%.

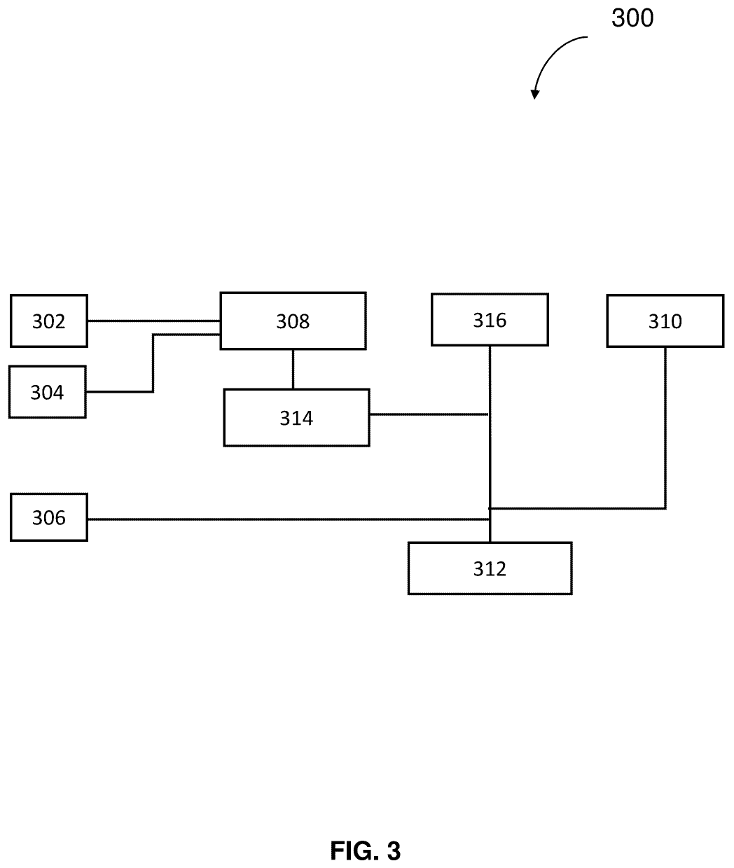

FIG. 3 is a block diagram of a system 300 for a vapor deposition, according to some embodiments. As shown in FIG. 3, in some embodiments, the system 300 comprises a feed gas comprising O₂ and N₂. In some embodiments, the O₂ is supplied from an oxygen source 302 and the N₂ is supplied from a nitrogen source 304. Although the O₂ and the N₂ are shown being supplied in separate gas streams, it will be appreciated that other configurations are possible, such as, for example and without limitation, the O₂ and the N₂ can be supplied in a single stream, or more than two streams, among other things. The O₂ from oxygen source 302 and the N₂ from nitrogen source 304 are flowed to an ozone generator 308 to produce an ozone gas 314. In some embodiments, the ozone gas 314 comprises an ozone (O₃) component. In some embodiments, the ozone component comprises gas-component impurities from the impurities contained in the ozone generated by the ozone generator. In some embodiments, the ozone gas 314 is flowed to a deposition chamber 312. In some embodiments, a nitrogen oxide 316 gas is flowed to the deposition chamber 312. In some embodiments, the nitrogen oxide gas comprises at least one of nitrous oxide (N₂O), nitric oxide (NO), dinitrogen pentoxide (N₂O₅), nitrogen dioxide (NO₂), or any combination thereof. In some embodiments, a first precursor gas 310 is flowed to the deposition chamber 312. In some embodiments, a substrate located in the deposition chamber, is exposed to at least one of the ozone gas 314 and the nitrogen oxide gas 316, the first precursor gas 310, or any combination thereof.

For exposing a metal precursor gas (a first precursor gas) to a substrate having at least one structure with an aspect ratio of at least 10:1. In some embodiments, the system 200 comprises supplying the metal precursor source 210 and the substrate directly to the vapor deposition apparatus 312. In some embodiments, the system 300 comprises an inert source 306 for supplying an inert gas, such as, for example and without limitation, N₂ to the vapor deposition apparatus 312. In some embodiments, the system 300 comprises supplying the inert source 306 directly to the vapor deposition apparatus 312.

In some embodiments, an inert source 306 is flowed to the deposition chamber 312. In some embodiments the inert source 306 comprises N₂. In some embodiments, the inert source 306 provides a continuous flow of N₂ to the deposition chamber. In some embodiments, the inert source 306 may be provided to dilute the third gas precursor 314. In some embodiments, the inert source 306 is supplied in a concentration that is not enough to increase the step coverage.

In some embodiments, a vapor deposition process is conducted to form a film on, at least one structure of a substrate, on the substrate, wherein the film has a step coverage of at least 50%.

### Example 1

Various hafnium tetrachloride (HfCl₄) films were deposited on substrates having high-aspect ratio structures by an atomic layer deposition process. The deposition process involved 100 to 200 cycles in which the substrate was exposed to HfCl₄ and an oxidation gas. Each sample involved a substrate having a trench structure with an aspect ratio of 11:1. Each sample was exposed to the HfCl₄ and co-reactant gas at a temperature of 300° C. Each sample had a different co-reactant gas. Sample 1 used O₃ as the co-reactant. Sample 2 used water (H₂O) as the co-reactant. Sample 3 used O₃ and N₂O as the co-reactant. The growth per cycle (GPC, Anstroms/Cycle) was measured. The results are summarized in Table 1 below.

TABLE 1

| | | Co- | Temperature | |
|---|---|---|---|---|
| | Precursor | reactant | (° C.) | GPC(Å/c) |
| Sample 1 | HfCl₄ | O₃ | 300 | 0.1 |
| Sample 2 | HfCl₄ | H₂O | 300 | 0.7 |
| Sample 3 | HfCl₄ | N₂O + O₃ | 300 | 1.0 |

The results presented in Table 1 highlight the improvements achieved by introducing N₂O into the process alongside O₃ mixture. Sample 1, which used only O₃ in the ALD process, was observed to have a low growth per cycle (GPC), measuring only 0.1 Å/c. Sample 2, which used only H₂O in the ALD process, was observed to have poor film uniformity. Sample 3, which used N₂O+O₃ in the ALD process, was observed to have improved GPC and film uniformity.

### Example 2

Various HfO₂ films were deposited on substrates having high-aspect ratio structures by an atomic layer deposition (ALD) process. The deposition process involved 100 to 200 cycles in which the substrate was exposed to HfCl₄ and an oxidation gas to achieve the desired thickness of the HfO₂ film. 300 mm Si (100) wafers were used as the substrates. Each sample involved a substrate having an aspect ratio of 11:1. Each sample was exposed to a hot wall crossflow reactor. Each sample was exposed to HfCl₄ vapor followed by an exposure to an O₃ mixture vapor. The ALD process was conducted under a pressure of approximately 3 Torr and a temperature at 300° C. within the reactor environment. O₃ was generated using an MKS O₃ generation system with a power input of 1000 W. N₂ gas was introduced into the oxygen feed at a concentration of 100 PPM for the O₃ generator. As a result, the O₃ generation system produced a mixture containing 14.3 mol % O₃ in O₂. The total O₃ mixture flow rate into the ALD reactor was maintained at 1300 standard cubic centimeters per minute (sccm). Simultaneously, nitrogen oxide (N₂O) gas was delivered into the system at the flow rate between 140 to 1000 sccm. The deposited HfO₂ thin film is characterized using techniques such as scanning electron microscopy (SEM) and ellipsometer to evaluate its step coverage and thickness. The growth per cycle (GPC, Anstroms/Cycle) and step coverage over the trench structure were measured. The results are summarized in Table 2 below.

TABLE 2

| | | | O₃ | | |
|---|---|---|---|---|---|
| | | N₂O | mixture | Grow | |
| | | flow | flow | rate | Step |
| | Co-reactant | (SCCM) | (SCCM) | (Å/c) | Coverage |
| Sample 1 | 14.3 mol % | 0 | 1300 | 0.1 | 28% |
| | O₃ in O₂ | | | | |
| Sample 2 | N₂O + 14.3 | 1000 | 1300 | 1.01 | 79% |
| | mol % O₃ in | | | | |
| | O₂ | | | | |
| Sample 3 | N₂O + 14.3 | 560 | 1300 | 0.98 | 76% |
| | mol % O₃ in | | | | |
| | O₂ | | | | |
| Sample 4 | N₂O + 14.3 | 280 | 1300 | 0.90 | 78% |
| | mol % O₃ in | | | | |
| | O₂ | | | | |
| Sample 5 | N₂O + 14.3 | 140 | 1300 | 0.84 | 72% |
| | mol % O₃ in | | | | |
| | O₂ | | | | |

The results presented in Table 2 highlight the improvements achieved by introducing N₂O into the process alongside O₃ mixture. Sample 1, which used only O₃ in the ALD process, was observed to have a low growth per cycle (GPC), measuring only 0.1 Å/c. The limited growth rate indicates inefficient deposition of the HfO₂ thin film. Samples 2-5, which introduced N₂O into the system in addition to O₃ mixture, the GPC increased substantially to about 1 Å/cycle. The tenfold increase in growth rate demonstrates the enhanced deposition efficiency achieved by the combined use of N₂O and O₃ mixture. Similarly, the step coverage of the deposited thin film was found to be low in Sample 1, with a measured coverage of only 28%. This indicates poor conformality of the film, particularly on sidewalls and other non-planar surfaces. In contrast, the introduction of N₂O into the ALD process resulted in a significant improvement in step coverage, reaching 79% in Sample 2. This enhanced step coverage indicates better film uniformity and conformality, resulting in improved film quality and device performance.

### ASPECTS

Various Aspects are described below. It is to be understood that any one or more of the features recited in the following Aspect(s) can be combined with any one or more other Aspect(s).
Aspect 1. A method comprising:
   simultaneously flowing an ozone gas from an ozone generator to a deposition chamber and flowing a nitrogen oxide gas from a first source to the deposition chamber;
   flowing a first precursor gas from a second source to the deposition chamber; and
   exposing a substrate located in the deposition chamber to at least one of the ozone gas and the nitrogen oxide gas, the first precursor gas, or any combination thereof,
      wherein the substrate has at least one structure with an aspect ratio of at least 10:1;
      wherein the exposing is sufficient to form a film having a step coverage of at least 50%.
Aspect 2. The method according to Aspect 1, wherein the method does not comprise flowing the nitrogen oxide gas from the first source to the ozone generator.
Aspect 3. The method according to any one of Aspects 1-2, wherein the exposing is sufficient to increase a growth rate cycle of the substrate.
Aspect 4. The method according to any one of Aspects 1-3, wherein the nitrogen oxide gas comprises nitrous oxide (N₂O).
Aspect 5. The method according to any one of Aspects 1-4, wherein the exposing comprises exposing the substrate to the ozone gas and the nitrogen oxide gas; and separately exposing the substrate to the first precursor gas.
Aspect 6. The method according to any one of Aspects 1-5, wherein the exposing is sufficient to form a film on the at least one structure having a step coverage of at least 90%.
Aspect 7. The method according to any one of Aspects 1-6, wherein the exposing the substrate to the ozone gas and the nitrogen oxide gas comprises a second precursor gas,
   wherein the second precursor gas comprises:
      10% to 60% by volume of the nitrogen oxide gas based on a total volume of the second precursor gas; and
      40% to 90% by volume of the ozone gas based on the total volume of the second precursor gas.
Aspect 8. The method according to any one of Aspects 1-7, wherein the exposing the substrate to the ozone gas and the nitrogen oxide gas comprises a second precursor gas,
   wherein the second precursor gas comprises:
      50% by volume of the nitrogen oxide gas based on a total volume of the second precursor gas; and
      50% by volume of the ozone gas based on the total volume of the second precursor gas.
Aspect 9. The method according to any one of Aspects 1-8, wherein the nitrogen oxide gas comprises at least one of nitrous oxide (N₂O), nitric oxide (NO), dinitrogen pentoxide (N₂O₅), nitrogen dioxide (NO₂), or any combination thereof.
Aspect 10. The method according to any one of Aspects 1-9, wherein the film comprises:
   a metal oxide or metalloid oxide; and
   a concentration of less than 1×10²⁰ hydrogen atoms per cubic centimeter as measured by SIMS.
Aspect 11. The method according to any one of Aspects 1-10, wherein the film comprises at least one of a hafnium oxide, a zirconium oxide, an aluminum oxide, a titanium oxide, a tantalum oxide, a niobium oxide, a vanadium oxide, a gallium oxide, an indium oxide, a silicon oxide, or any combination thereof.
Aspect 12. The method according to any one of Aspects 1-11, wherein prior to the step of flowing an ozone gas, the method comprises:
   flowing a nitrogen gas from a nitrogen source to the ozone generator; and
   flowing an oxygen gas from an oxygen source to the ozone generator;
      wherein the ozone generator produces the ozone gas.
Aspect 13. The method according to any one of Aspects 1-12, wherein the nitrogen gas comprises:
   50 ppm to 200 ppm of N₂.
Aspect 14. The method according to any one of Aspects 1-13, wherein the deposition chamber has a temperature in a range of 150° C. to 350° C.
Aspect 15. A device comprising:
   a substrate having at least one structure with an aspect ratio of at least 10:1; and
   a film located on the at least one structure,
   wherein the film has a step coverage of at least 50%.
Aspect 16. The device according to Aspect 15, wherein the film has a step coverage of at least 90%.
Aspect 17. The device according to any one of Aspects 15-16, wherein the film comprises:
   a metal oxide or metalloid oxide; and
   a concentration of less than 1×10²⁰ hydrogen atoms per cubic centimeter as measured by SIMS.
Aspect 18. The device according to any one of Aspects 15-17, wherein the film comprises at least one of a hafnium oxide, a zirconium oxide, an aluminum oxide, a titanium oxide, a tantalum oxide, a niobium oxide, a vanadium oxide, a gallium oxide, an indium oxide, a silicon oxide, or mixtures thereof.

What is claimed is:

1. A method comprising:
simultaneously flowing an ozone gas from an ozone generator to a deposition chamber and flowing a nitrogen oxide gas from a first source to the deposition chamber;
flowing a first precursor gas from a second source to the deposition chamber; and
exposing a substrate located in the deposition chamber to at least one of the ozone gas and the nitrogen oxide gas, the first precursor gas, or any combination thereof,
wherein the substrate has at least one structure with an aspect ratio of at least 10:1;
wherein the exposing is sufficient to form a film having a step coverage of at least 50%.

2. The method of claim 1, wherein the method does not comprise flowing the nitrogen oxide gas from the first source to the ozone generator.

3. The method of claim 2, wherein the exposing is sufficient to increase a growth rate cycle of the substrate.

4. The method of claim 1, wherein the nitrogen oxide gas comprises nitrous oxide (N₂O).

5. The method of claim 1, wherein the exposing comprises exposing the substrate to the ozone gas and the nitrogen oxide gas; and separately exposing the substrate to the first precursor gas.

6. The method of claim 1, wherein the exposing is sufficient to form a film on the at least one structure having a step coverage of at least 90%.

7. The method of claim 1, wherein the exposing is sufficient to form a film on the at least one structure having a step coverage of 50% to 99%.

8. The method of claim 1, wherein the exposing the substrate to the ozone gas and the nitrogen oxide gas comprises a second precursor gas,
wherein the second precursor gas comprises:
10% to 60% by volume of the nitrogen oxide gas based on a total volume of the second precursor gas; and
40% to 90% by volume of the ozone gas based on the total volume of the second precursor gas.

9. The method of claim 1, wherein the exposing the substrate to the ozone gas and the nitrogen oxide gas comprises a second precursor gas,
wherein the second precursor gas comprises:
40% to 60% by volume of the nitrogen oxide gas based on a total volume of the second precursor gas; and
40% to 60% by volume of the ozone gas based on the total volume of the second precursor gas.

10. The method of claim 1, wherein the nitrogen oxide gas comprises at least one of nitrous oxide (N₂O), nitric oxide (NO), dinitrogen pentoxide (N₂O₅), nitrogen dioxide (NO₂), or any combination thereof.

11. The method of claim 1, wherein the film comprises:
a metal oxide or metalloid oxide; and
a concentration of less than 1×10²⁰ hydrogen atoms per cubic centimeter as measured by SIMS.

12. The method of claim 1, wherein the film comprises at least one of a hafnium oxide, a zirconium oxide, an aluminum oxide, a titanium oxide, a tantalum oxide, a niobium oxide, a vanadium oxide, a gallium oxide, an indium oxide, a silicon oxide, or any combination thereof.

13. The method of claim 1, wherein prior to the step of flowing an ozone gas, the method comprises:
flowing a nitrogen gas from a nitrogen source to the ozone generator; and
flowing an oxygen gas from an oxygen source to the ozone generator;
wherein the ozone generator produces the ozone gas.

14. The method of claim 13, wherein the nitrogen gas comprises:
50 ppm to 200 ppm of N₂.

15. The method of claim 1, wherein the deposition chamber has a temperature in a range of 150° C. to 350° C.

16. A device comprising:
a substrate having at least one structure with an aspect ratio of at least 10:1; and
a film located on the at least one structure,
wherein the film has a step coverage of at least 50%.

17. The device of claim 16, wherein the film has a step coverage of at least 90%.

18. The device of claim 16, wherein the film comprises:
a metal oxide or metalloid oxide; and
a concentration of less than 1×10²⁰ hydrogen atoms per cubic centimeter as measured by SIMS.

19. The device of claim 16, wherein the film comprises at least one of a hafnium oxide, a zirconium oxide, an aluminum oxide, a titanium oxide, a tantalum oxide, a niobium oxide, a vanadium oxide, a gallium oxide, an indium oxide, a silicon oxide or any combination thereof.
